(19) United States
(12) Patent Application Publication
(10) Pub. No.: US 2002/0196352 A1
(43) Pub. Date: Dec. 26, 2002

(54) Compensation of pixel source follower variations in CMOS imager

(76) Inventor: Christian Boemler, Cortland, NY (US)

Correspondence Address: BERNHARD P. MOLLDREM, JR., 2ND FLOOR, MONROE BUILDING, 333 EAST ONONDAGA STREET, SYRACUSE, NY, 13202, US

(21) Appl. No.: 10/153,028

(22) Filed: May 21, 2002

Related U.S. Application Data
(60) Provisional application No. 60/292,309, filed on May 21, 2001.

(51) Int. Cl. H04N 3/14

(52) U.S. Cl. 348/241; 348/302; 348/300

(57) ABSTRACT

An arrayed source-follower buffer arrangement compensates between gains of respective columns of a pixel array. For each said column of the pixel array the source-follower buffer arrangement includes an operational amplifier having a signal input, an output, and a feedback terminal and a source-follower amplifier disposed with a gate coupled to the output, a terminal connected to a bias voltage, and an output terminal connected to the feedback terminal of the operational amplifier. The bias voltage may be matched to a bias voltage applied to the pixel array. A source-follower construction compensates for body effect and load effect by having a reference source follower per column of the same dimensions used as in the pixel array.

### BACKGROUND OF THE INVENTION

This invention relates to solid-state imaging devices, either linear or areal, monochrome or color, and using visible light, infrared, or x-ray sensitive pixels. More specifically, an arrayed source follower buffer employs a compensation scheme to counteract the lack of unity gain operation. The invention utilizes a single operational amplifier per column with a reference source follower in its feedback to invert the non-unity gain of source followers in the pixels and thus produce a unity gain buffering from the pixel of a selected row to the pixel amplifier output.

### DESCRIPTION OF THE PRIOR ART

In a typical CMOS image sensor, a source follower FET amplifier is utilized to buffer the pixel signal, in an attempt to achieve “unity” gain, onto a single column wire. A typical implementation in an array image sensor has row select wires selecting the row to be read out in parallel on the respective Col_N wires. The selected source follower needs a given load for each column, and that load can be a resistor or may be an FET. An optional buffer and a multiplexer drives the column signals sequentially onto a single video bus wire. On the output signal path, a sample-and-hold circuit is employed so that the pixels can be shut off to prevent them from accumulating charge during readout.

The structure for a pixel is comprised of a Reset_FET from the pixel to VDD that can reset the pixel contents to black when selected, a Sense_FET that constitutes the source follower and a select FET to select a given row at a time to connect onto the Column wires. One of the major problems with this construction is that the N-FET source follower is not a unity-gain amplifier but will have this small signal gain characteristic:

$${A}_{V} = \frac{{g}_{M1}}{{g}_{M1} + {g}_{S1} + {g}_{DS1} + {g}_{LOAD}} < 1$$

Where g_{M1} is the transistor transconductance, g_{S1} is the body effect equivalence (dependent on the source voltage), g_{DS1} is the drain source admittance and 9_{LOAD} is the load admittance. From the above equation it is apparent that the gain of the source follower decreases with increasing body effect, with decreasing drain-source resistance, with decreasing load resistance. The g_{DS} term is usually small because the MOSFET's used are of a smaller size, the g_{LOAD} term is large when using a low impedance load to pull the highly capacitive Col_N lines low. The majority of the gain decrease is from the body effect, which depends on the pixel voltage as well as other MOSFET parameters. This body effect is the key reason that the gain of a source follower is less than one (gains of 0.8 to 0.9 are typical) and the reason that the gain tends to vary both with the pixel voltage and with any mismatching in the column loads. This variance among columns shows up in the image as undesired column fixed pattern noise.

The implementation described in the previous paragraph (and described, e.g., in U.S. Pat. 5,296,696) is the basis for many CMOS image sensors where the source follower construction is the main reason that CMOS image sensors have acquired a reputation of being prone to fixed pattern noise. One of the best solutions to date for this problem has been the PVS Active Column Sensor (ACS) as described in U.S. Pat. 6,084,229. That construction employs a feedback loop back into the columns via the source (SRC) and drain (DRN) wires. An alternative, and basically equivalent solution is described in U.S. Pat. 6,130,423.

Basically the structures in these two above-mentioned patents are based on splitting the operational amplifier (OpAmp) and distributing the positive amplifier input FET (or both the positive and negative amplifier input FET's) across a column of the sensor array. The selected row will be the FET used as part of the OpAmp with the feedback compensating for the body effect and other effects to produce a feedback-compensated unity-gain amplification.

With the ACS sensor, each pixel has to have a minimum of three transistors: a Reset-FET, Select-FET, and a Pixel_Sense-FET. Each pixel also has to have five wires running through it: a Reset wire, a Row_Select wire, a drain (DRN) wire, a source (SRC) wire, a Reset_Bias wire, and a common or ground (GND) wire (in the substrate). The approach described in U.S. Pat. 6,130,423 is similar, but requires an extra transistor and two extra wires per column.

A serious limitation to both of the above-described solutions is that two of the central parts in the operational amplifier are connected via long wires to all the pixels in a column. This places a significant amount of capacitances to the OpAmp input stage and that limits the speed and stability of the OpAmp.

### OBJECTS AND SUMMARY OF THE INVENTION

It is an object of this invention to provide a simple mechanism to control or eliminate fixed pattern noise in the CMOS imager.

It is another object to employ a source follower construction to achieve a unity gain for each column of the CMOS imager.

In accordance with an aspect of this invention, an arrayed source-follower buffer arrangement for compensating between gains of respective columns of a pixel array; wherein for each said column of the pixel array the source-follower buffer arrangement includes

a) an operational amplifier having a signal input, an output, and a feedback terminal; and

b) a source-follower amplifier disposed with a gate coupled to said output, a terminal connected to a bias voltage, and an output terminal connected to the feedback terminal of the operational amplifier. The bias voltage may be matched to a bias voltage applied to the pixel array.

This invention employs a source follower construction and addresses the problem by compensating for the body effect and load effect by having a reference source follower per column of the same dimensions used as in the pixel array. A feedback amplifier structure regulates the “pixel” input of the reference amplifier so that the selected pixel source follower output and the reference source follower outputs are the same. The feedback amplifier structure compensates for the body effect and is therefore equivalent to the true pixel value in the selected row. Matching the devices used to construct the load in the array load and the reference load can significantly reduce variances in the impedance and thus can reduce any gain variance between the array source followers and the reference source follower.

The above and many other objects features and advantages of the invention can be understood from the ensuing description of preferred embodiment(s), which are to be considered in connection with the accompanying Drawing.

### BRIEF DESCRIPTION OF THE DRAWING

FIG. 1 is a schematic circuit diagram of a representative portion of a CMOS imager according to the prior art.

FIG. 2 is a schematic circuit diagram of a CMOS imager according to one embodiment of this invention.

FIG. 3 is a schematic circuit diagram of another embodiment, having an output bus precharge feature.

FIG. 4 is a schematic circuit diagram of a further embodiment.

FIG. 5 is an illustration of a detail of the construction of the above embodiments for explaining a chip layout advantage.

### DETAILED DESCRIPTION OF THE PREFERRED EMBODIMENTS

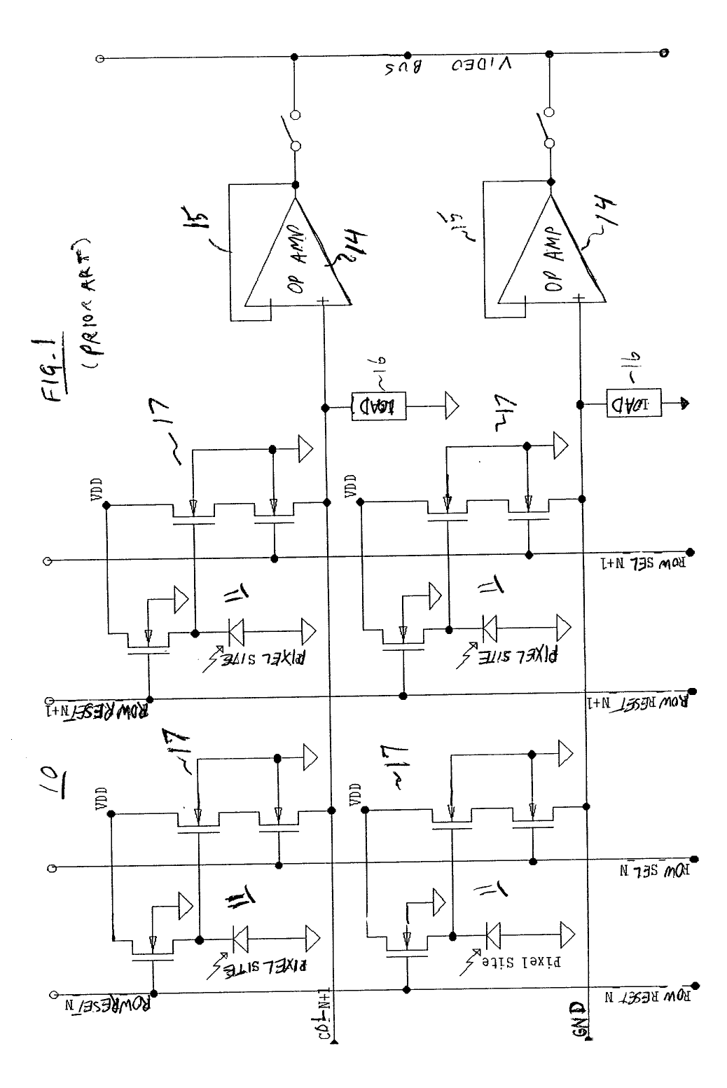

For purposes of comparison, FIG. 1 illustrates the general construction of a CMOS imager 10 according to the current state of the art. Here there are shown pixels or picture element circuits 11, in representative columns N and N+1. Shown here are Row_Reset wires, Row_Se1 wires, and column output wires Col_N, Col_N+1, and ground GND. For each column there is a column amplifier 14, in the form of an OpAmp, and each having a feedback loop 15, with an output going to a video bus Video_Bus, and (+) and (−) inputs, with the column wire going to the (+) input and the feedback loop 15 going to the (−) input. At each of the (+) inputs of the column amplifiers there is a compensating load 16, which typically is an ohmic resistance. An FET circuit 17 in each pixel element can form part of the column amplifier 14. Outputs of the amplifiers 14 are switched in sequence onto a video output bus Video_Bus.

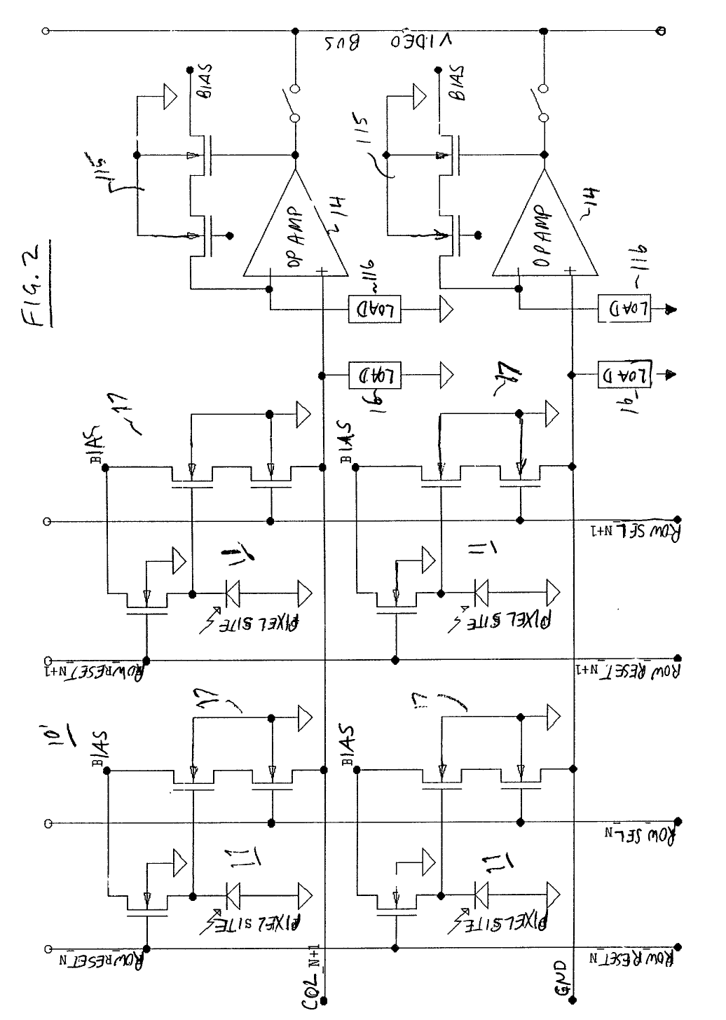

By comparison of FIG. 1 with FIG. 2, which illustrates an improvement according to an embodiment of this invention, is will be seen that in FIG. 2 a reference source follower 115 forms the short feedback loop of the column operational amplifier 14, as compared with the ACS system in which the pixel FET is itself a part of the operational amplifier. If there are variances in bulk effect across the Col_N-axis of the array, the variance in each of two matched column loads 16, 16 are minimal and if the operational amplifier has a higher open loop gain, then the output of the operational amplifier 14 will reflect the pixel voltage of the selected row with a resulting feedback compensated unity gain. The body effect (and other effects) are compensated for by means of the source follower can be illustrated by the following equation:

$$pixelSignal \times Avpix = AmplifierOut \times Avref , Avpix = Avref ⇒ AmpliferOut = \frac{PixelSignal \times Avpix}{Avref} = PixelSignal$$

This compensation makes the OpAmp output become exactly equal to the Pixel signal because AV_{ref} and AVₚᵢₓ are both the same if the gate voltages and the load on the two source followers are the same. Accordingly, there are equal value loads 16 and 116 on the (+) and (−) inputs respectively of the amplifier 14.

In practice, the operational amplifier 14 can have significant offset errors—especially if laid out in an arrayed structure, but a compensated double sampling circuit (CDS) (not shown) disposed after the OpAmp 14 can compensate for those offset errors. A sample-and-hold (not shown) may be required to prevent further exposure of pixels during readout.

The fact that there is only one signal wire per column running across the array, instead of both source (SRC) and drain (DRN), is a significant improvement over the ACS arrangement. In addition, the fact that no part of operational amplifier feedback loop is loaded by long column wires results in faster settling time and decreases the line overhead time when selecting a row.

Another improvement is that by reducing the load impedance, the video readout speed can be increased (i.e., if the loads 16 and 1 16 are each an N-FET, then altering the gate voltage alters the impedance), on account of an even lower source follower gain (that will be compensated by this invention). If no rows are selected and the voltage “V_{DD}” of the reference source follower is turned on and off by a logic signal, then a low power mode is possible, where it is only the operational amplifiers 14 that draw some quiescent current to drive the video bus.

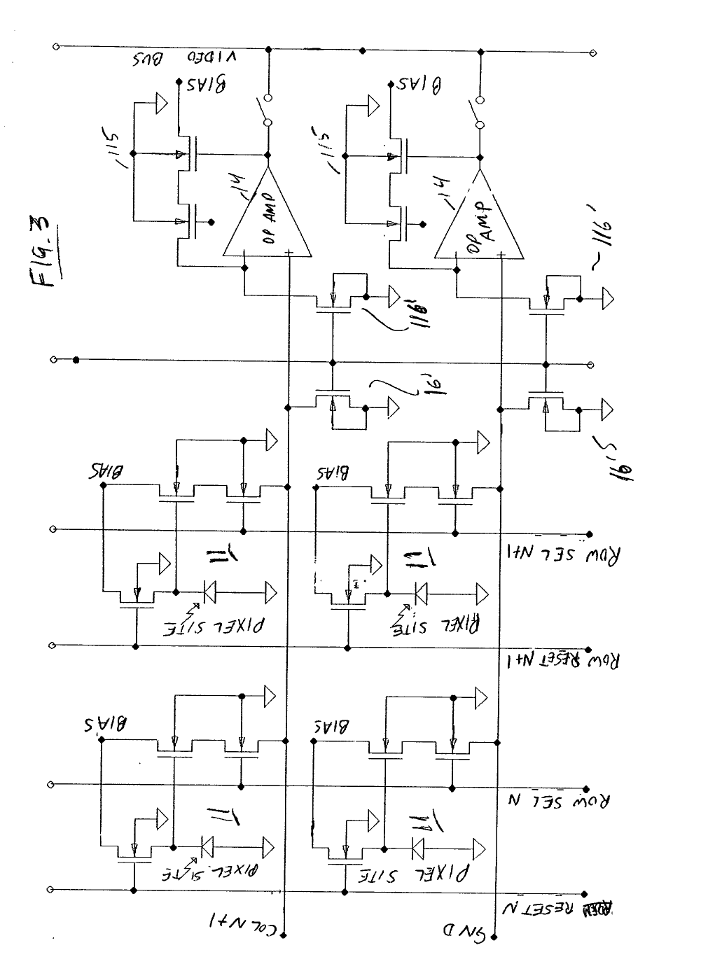

An example of an FET-loaded embodiment is shown in FIG. 3, wherein a source-follower FET 16′ is coupled to the (+) input and another source follower 116′ is coupled to the (−) input of each respective amplifier 14. Here a pre-charge wire 19 connects to the gates of these source follower FETs 16′ and 116′.

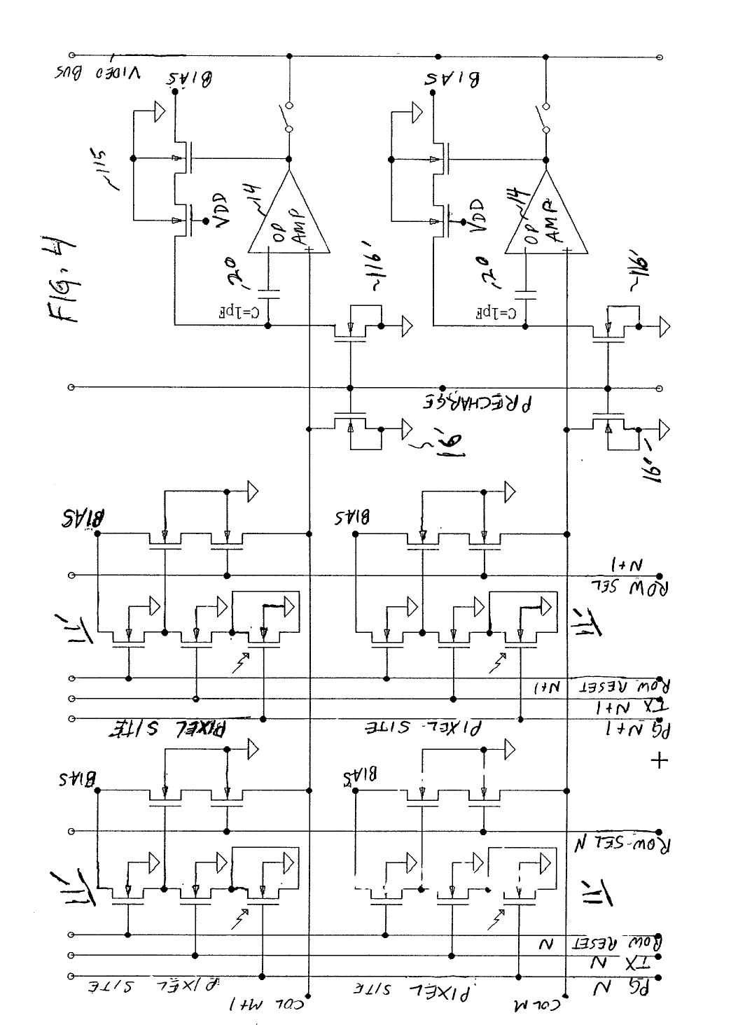

FIG. 4 illustrates another embodiment in which the pixels 11′ are formed of photo-sensitive FETs. In this case, an input capacitor 20 is situated at the (−) input of each amplifier 14 for DC isolation of the (−) input from the respective feedback circuit 115 and load source-follower 116′. The capacitor 20 represents an offset-compensating Miller capacitor, where the difference between the reset level of the selected source follower and a constant referencevoltage is subtracted from the video levels of that selected source follower. The pixel is operated by keeping PG high to integrate electrons and TX low to block photo-generated charge from going into the source follower. To get the reset level, the reset is activated and then de-activated and the source follower input then contains the bias plus charge injection and kTC noise of the reset FET into the source follower input capacitance. TX is brought high and PG is brought low, and TX is brought low again to transfer the photo-generated charge into the source follower input. The source follower will have an input voltage equal to the sum of the reset level plus the photo-generated charge. Utilizing the Miller-capacitor scheme will enable the amplifier to subtract the reset level from the photo-generated charge into the source follower gate and thus produce a voltage output dependent only on the photo-generated charge and the source follower gate input capacitance. This scheme also removes any linear (i.e., offset) variations, where source follower Vₗ variations are the most dominant.

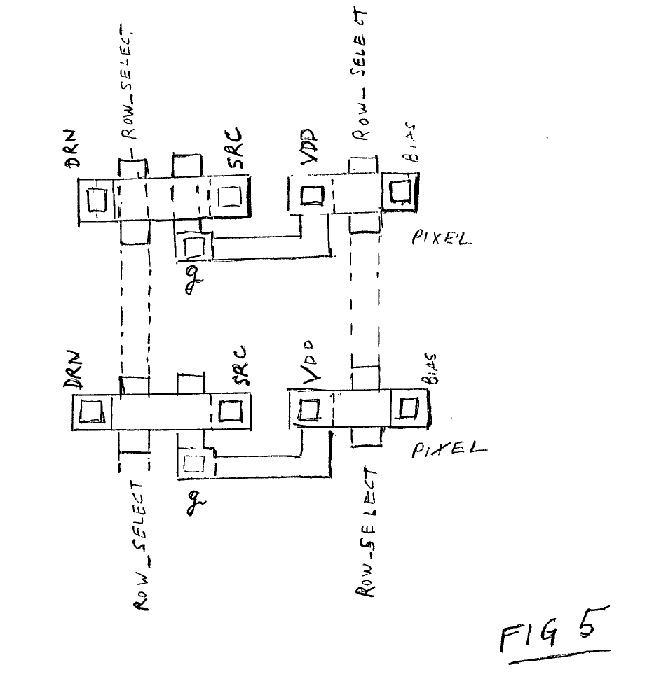

Another benefit to the source follower being reset to the same signal as the source follower is purely a chip layout issue, and results in compact design, as generally illustrated in FIG. 5. The Pixel Sense_FET and the Reset_FET both have a drain (DRN) connected to Bias (or V_{DD}) and can thus be laid out as shared-drain with a smaller layout compared to the ACS arrangement.

While the invention has been described in reference to certain preferred embodiments, it should be understood that the invention is not limited to those embodiments, but that many modifications and variations would present themselves to those skilled in the art without departing from the scope and spirit of the invention, as defined in the Appended Claims.

I claim:

1. An arrayed source-follower buffer arrangement for compensating between gains of respective columns of a pixel array; wherein for each said column of the pixel array the source-follower buffer arrangement includes
a) an operational amplifier having a signal input, an output, and a feedback terminal; and
b) a source-follower amplifier disposed with a gate coupled to said output, a terminal connected to a bias voltage, and an output terminal connected to the feedback terminal of the operational amplifier.

2. The buffer arrangement of claim 1 wherein said bias voltage is matched to a bias voltage applied to the pixel array.

3. The buffer arrangement of claim 1, wherein said operational amplifier has matching loads applied to each of a pair of (+) and (−) inputs thereof.

4. The buffer arrangement of claim 3, wherein said loads are each formed of a source follower.

5. The buffer arrangement of claim 4, wherein an adjustable bias is applied to gate terminals of said source followers to control the load values thereof.
